(19) United States
(12) Patent Application Publication
(10) Pub. No.: US 2024/0237193 A1
(43) Pub. Date: Jul. 11, 2024

(54) DUAL IN-LINE MEMORY MODULE (DIMM) SOLUTION THAT INCLUDES FLEXIBLE TRANSMISSION LINES

(71) Applicant: Intel Corporation, Santa Clara, CA (US)

(72) Inventors: Yi HUANG, Shanghai (CN); Xiaoning YE, Portland, OR (US); Kai XIAO, Portland, OR (US); James A. McCALL, Portland, OR (US); Yanjie ZHU, Folsom, CA (US)

(21) Appl. No.: 18/618,075

(22) Filed: Mar. 27, 2024

(30) Foreign Application Priority Data
Mar. 8, 2024 (WO) PCT/CN2024/080740

(51) Int. Cl. H05K 1/02; H05K 1/11; H05K 1/14

(52) U.S. Cl. CPC H05K 1/0253; H05K 1/117; H05K 1/141; H05K 2201/10189

(57) ABSTRACT

An apparatus is described. The apparatus includes a memory module. The memory module includes a first printed circuit board having a first transmission line. The first printed circuit board has memory chips disposed thereon. The memory module includes a second printed board having a second transmission line that is coupled to the first transmission line to form a signal path through the first and second printed circuit boards. The second printed circuit board has greater flexibility than the first printed circuit board. The memory module includes a connector to align an I/O that is coupled to the second transmission line with a corresponding I/O that is associated with a motherboard that is to send and/or receive a signal to and/or from the signal path.

### CLAIM OF PRIORITY

This application claims the benefit of priority to Patent Cooperation Treaty (PCT) Application No. PCT/CN2024/080740, filed Mar. 8, 2024. The entire content of that application is incorporated by reference.

### BACKGROUND

As computing system clock and signal frequencies become higher and higher, engineers are faced with the challenge of preserving the integrity of signals that pass through a connector between a modular component and a larger system that the modular component plugs in/out of.

### BRIEF DESCRIPTION OF FIGURES

FIG. 1a (prior art) shows a transmission line;

FIG. 1b (prior art) shows a dual in-line memory (DIMM) solution;

FIG. 2 shows a DIMM solution with a flexible transmission line;

FIGS. 3a, 3b, 3c, 3d, 3e, 3f, 3g, 3h, 3i, 3j, 3k, 3l, 3m and 3n pertain to various embodiments of a DIMM solution with flexible PCBs;

FIGS. 4a, 4b depict a DIMM solution with flexible PCBs that are monolithically integrated with a DIMM PCB;

FIGS. 5a, 5b, 5c, 5d, 5e, 5f, 5g, 5h, 5i, 5j, 5k, 5l, 5m, 5n, 5o, 5p, 5q, 5r and 5s pertain to a method for manufacturing a monolithically integrated DIMM PCB with flexible PCBs;

FIG. 6 shows a computing system.

### DETAILED DESCRIPTION

When the respective wavelengths of an electronic signal's frequency components become comparable to the dimensions of the electronic circuit that is propagating the signal, signal integrity problems can arise unless the circuit was designed to include specific structures that mitigate the signal integrity issues. Specifically, the circuit should be formed to include special signal lines (referred to as transmission lines) that ensure the integrity of the signals that the signal structure propagates.

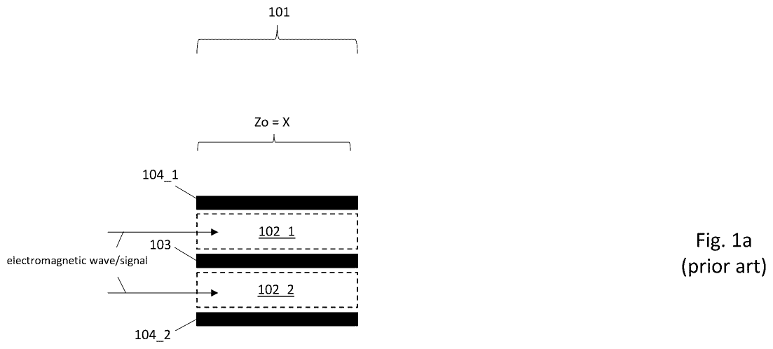

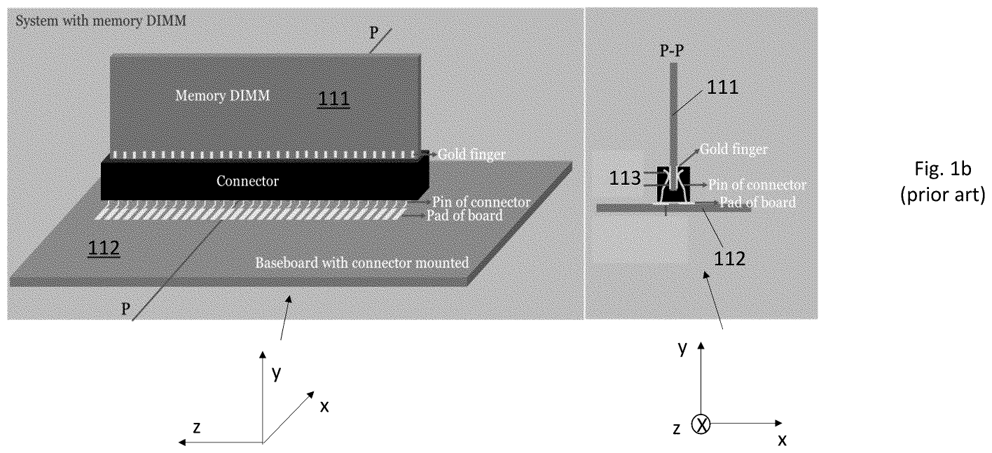

FIG. 1a shows a particular transmission line 101 referred to as a coplanar stripline transmission line. With a coplanar stripline transmission line, the signal is an electromagnetic wave that propagates in dielectric media 1021, 102_2 on either side of a central conductor 103. The dielectric media 1021, 102_2 are each between the central conductor 103 and a respective, outer “ground” conductor 104_1, 104_2.

The electric field components of the wave induce electric charges on the central conductor 103 as a function of the transmission line's three dimensional structure of conductors 103, 104_1, 104_2 and dielectric material 1021, 102_2, which, in turn, corresponds to the transmission line's “characteristic impedance”. Signal integrity is maintained by preserving the signal line's characteristic impedance along the signal path of the circuit structure.

Unfortunately, as observed in FIG. 1b, the circuitry that implement the interface between a dual in-line memory module (DIMM) 111 and a system motherboard 112 (also referred to as a baseboard) do not include transmission lines with controlled characteristic impedance as described just above. Specifically, the electrical signal connections 113 between the DIMM 111 and motherboard 112 are implemented not only as wire structures without outer ground conductors but also as “stubs”.

As the frequencies of the signals that are passed between a DIMM 111 and motherboard 112 continue to increase, their corresponding wavelengths have become comparable to the dimensions of the stubs 113 and other circuit structures that reside between the DIMM 111 and motherboard 112. As a consequence, signal integrity problems are becoming more troublesome at the DIMM/motherboard interface.

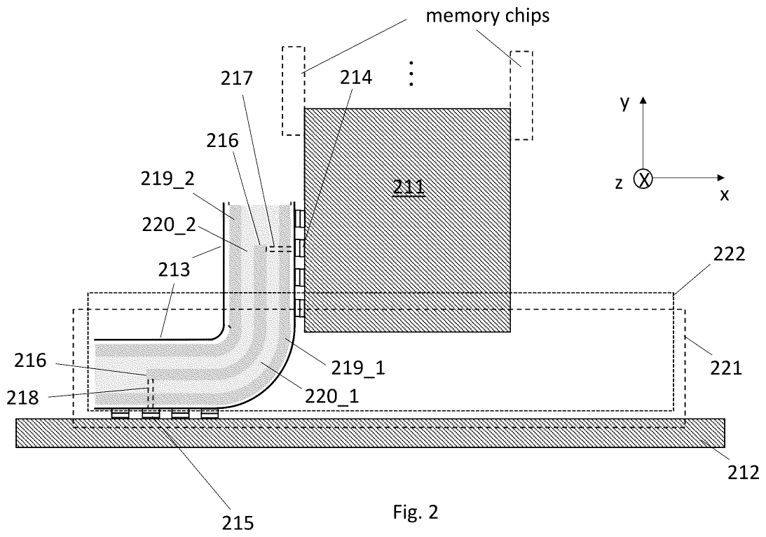

A solution, as observed in FIG. 2, is to incorporate well controlled transmission lines in the connection circuitry between a DIMM 211 and its motherboard 212. Here, as observed in FIG. 2, a flexible printed circuit board (PCB) 213 is patterned such that at least certain signal lines (e.g., signal lines that are to propagate high frequency signals) are implemented as respective transmission lines.

FIG. 2 shows one transmission line in detail. Specifically, a first pad 214 on the DIMM PCB 211 and a second pad 215 on the motherboard PCB 212 are electrically coupled through the flexible PCB 213 to propagate a particular signal between the DIMM 211 and motherboard 212. Both pads 214, 215 are coupled to inner conductor 216 of the flexible PCB 213 by way of respective vias 217 and 218. Here, vias 217 and 218 extend through openings (e.g., respective holes) formed in the flexible PCB's outer conductor 219_1, 219_2 and inner dielectric layers 220_1, 2202.

Importantly, inner conductor 216, inner dielectric layers 220_1, 220_2 and outer conductor layers 219_1, 219_2 implement a transmission line that maintains the integrity of the signal as it passes through the flexible PCB 213 between the motherboard and DIMM pads 214, 215. As a consequence of the transmission line implementation, signal integrity is maintained in the electrical connection between the DIMM PCB 211 and the motherboard PCB 212.

In various embodiments, the flexible PCB 213 and the DIMM PCB 211 (which typically has memory chips, a controller chip, buffer chips, etc. mounted thereon) are integrated together as a single product. A DIMM connector 221 (also referred to as a socket) is mounted to the motherboard 212. During installation of the integrated DIMM product 211, 213 to the motherboard 212, the DIMM 211 and its flexible PCB 213 are inserted into the connector 221. The connector 221 is shaped to cause the pads on the motherboard to align with their counterpart pads on the flexible PCB during the DIMM's insertion into the connector 221.

Alternatively or in combination, the connector 221 has a floor whose upward face has pads that are electrically coupled (e.g., soldered) to pads on the motherboard. In this case, the connector 221 is shaped to cause the connector's pads to be aligned with the motherboard-side pads of the flexible PCB 213 during the insertion of the integrated DIMM and flexible PCB product into the connector 221.

The DIMM PCB and flexible PCB integrated product can also include a connector 222 that is designed to be installed to the motherboard. The integrated product connector 222 can be shaped to include floors, arms, etc., that provide mechanical stability to (secure) the flexible PCBs and/or the DIMM PCB (e.g., to one another) and/or position and/or otherwise help guide the I/Os of the integrated product as it plugs into the motherboard connector 221 so the I/Os properly mate with their corresponding I/Os on the motherboard 212 or motherboard connector 221.

Notably, the flexible PCB has pads (not labeled in FIG. 2 for ease of drawing) that are aligned with corresponding pads on the DIMM PCB 211 and motherboard 212 to effect the desired electrical contact between the DIMM PCB 211 and the flexible PCB 213, and, the motherboard PCB 212 and the flexible PCB 213. In various embodiments, the pads on the flexible PCB 213 that couple to the DIMM PCB 211 are soldered to the DIMM PCB 211 to help form the complete integrated DIMM PCB and flexible PCB product. By contrast, in various embodiments, the pads of the flexible PCB pads that couple to the motherboard 212 or connector 221 are press fit so that the integrated DIMM PCB and flexible PCB product can be easily installed/removed to/from the motherboard 212.

In various embodiments, solder balls, micro-balls, micro-bumps, short leads, etc. can be used instead of pads as described above. All of these including pads can be more generally referred to as “input/outputs” (I/Os).

In various embodiments there can be many hundreds or thousands of separate/isolated inner conductors within the flexible PCB 213 to implement the many hundreds or thousands of separate wiring connections between the DIMM PCB 211 and the motherboard 212. Such isolated inner conductors can be, e.g., spaced apart along the z axis as depicted in FIG. 2 so that approximately the entire width of the DIMM PCB along the z axis is available to support I/O connections between the DIMM PCB 211 and the motherboard 212.

Moreover, although the flexible PCB layering structure observed in FIG. 2 only depicts a single transmission line layer, additional transmission line layers can be added to the flexible PCB 213 to further expand the number of I/O connections between the DIMM PCB 211 and the motherboard 212. For example, a layered dielectric/outer_conductor/dielectric/inner_conductor/dielectric/outer_conductor/dielectric structure can be added to the flexible PCB structure 213 observed in FIG. 2 to, e.g., effectively double the number of I/O transmission lines that the flexible PCB implements. A third layered structure can further be added to triple the number of I/O transmission lines, etc.

The flexible PCB's transmission line structures can be implemented as point-to-point connections between a motherboard I/O and a DIMM PCB I/O as observed in FIG. 2, and/or be formed to implement some form of branching and/or fanning-out from one end-point to another end-point. For example, a wiring structure within the flexible PCB 213 can be formed to have one physical connection on the motherboard side. The wiring structure branches out within the flexible PCB to N wiring structures and N corresponding I/O connections on the DIMM PCB side (where N is an integer greater than 1). The wiring structures including the branches can be implemented as transmission lines (e.g., where characteristic impedance is maintained at the 1:N branching location), or, as traditional wire structures.

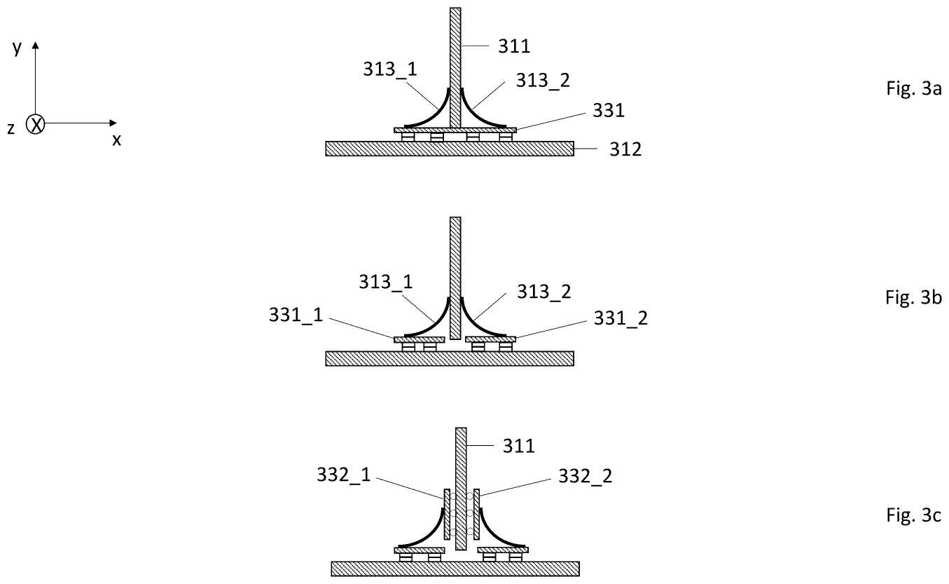

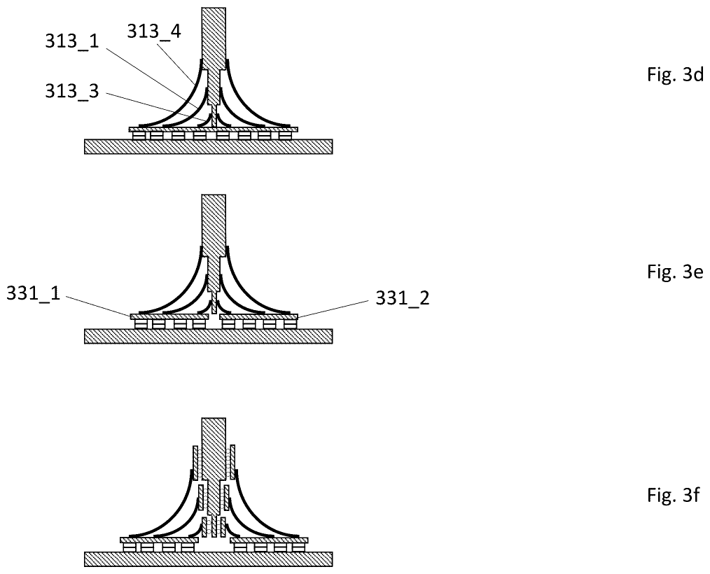

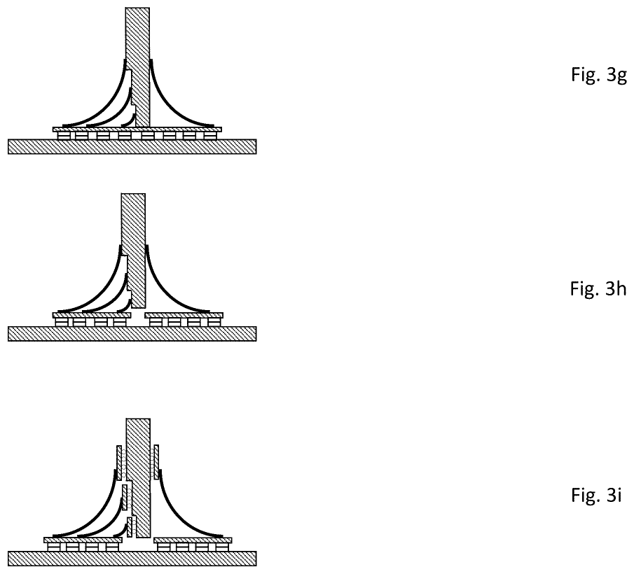

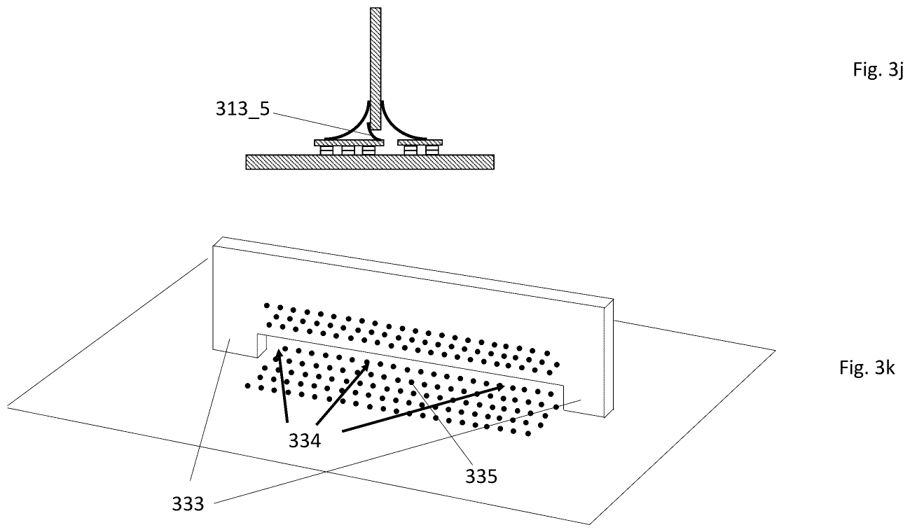

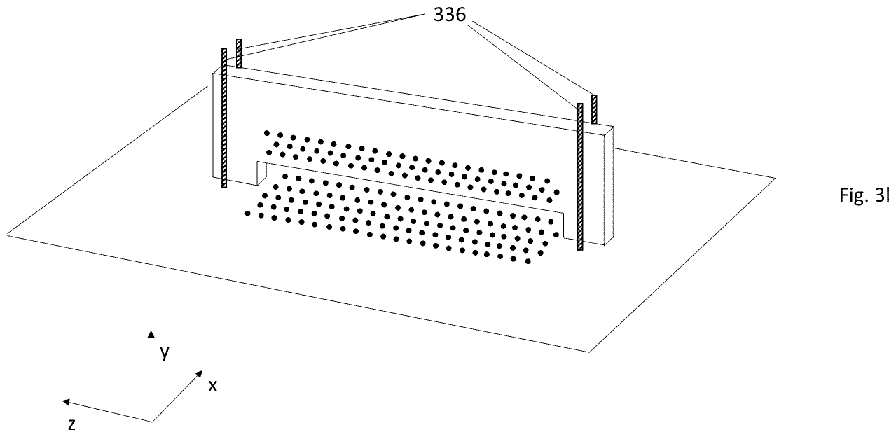

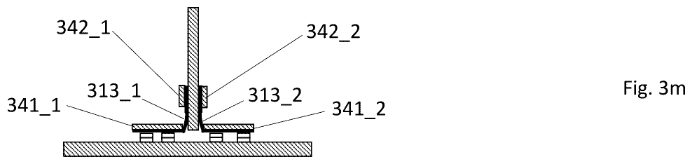

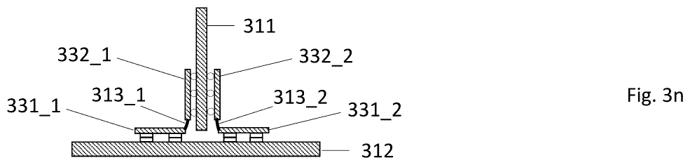

In short, many different flexible PCB implementations are possible between the motherboard 212 and DIMM PCB 211. FIGS. 3a through 3l show various embodiments of an integrated DIMM and flexible PCB product that connects to a motherboard. For ease of drawing the motherboard connector nor any connector that is part of the integrated DIMM PCB and flexible PCB product is shown.

FIG. 3a shows a first embodiment in which there are separate flexible PCBs 313_1, 313_2 for different faces of the DIMM PCB 211. The I/Os on the DIMM-side of both flexible PCBs 313_1, 313_2 are directly soldered to the DIMM PCB 311, but, the I/Os on the motherboard-side of both flexible PCBs 313_1, 313_2 is soldered to a “base” PCB 331. Here, the base PCB 331, in various embodiments, is a component of the integrated with DIMM PCB and flexible product that is mounted to the motherboard 312. The base PCB 331 can act, e.g., as a kind of substrate that allows for easy insertion and alignment of the integrated product into the connector (e.g., the base PCB 331 is rigid and precisely shaped to mate with the motherboard connector's corresponding shape).

FIG. 3b shows another approach but where each of the different flexible PCBs 313_1, 313_2 is connected to its own, dedicated base PCB 331_1, 331_2. The approach of FIG. 3b may assist the ease at which the integrated product is removed from the socket (e.g., the base PCBs 313_1, 313_2 are removed from the socket separately with less force than what a single base PCB would require).

In the embodiment of FIG. 3c, both ends of both flexible PCBs have a base PCB rather than having a base PCB only on the motherboard side. Because in various embodiments the flexible PCB connection to the DIMM PCB is a permanent connection (whereas the connection to the motherboard allows for easy insertion/removal through a socket), the I/Os of the base PCBs 3321, 332_2 on the DIMM PCB side of the flexible PCBs are soldered to the DIMM PCB, e.g., through solder ball attachment as depicted in FIG. 3c.

Having a base PCB 3321, 332_2 on the DIMM side of the flexible PCBs can enhance the reliability of the overall integrated product. For instance, stresses that are applied to the DIMM PCB, e.g., when the integrated product is being installed and/or removed to/from the motherboard socket, can result in subtle “bending” of the DIMM PCB (and/or the DIMM PCB can be warped when the product is fully seated in the connector). The bending or warping of the DIMM PCB can induce stresses/strains upon the soldered I/Os between the DIMM PCB and the flexible PCB. The solder balls observed at the DIMM PCB/flexible PCB interface may be able to absorb such stresses/strains better than, e.g., pad-to-pad soldered connections between the flexible PCB and the DIMM PCB.

Said another way, as observed in FIG. 3c, the flexible PCBs are already warped/bent according to the design of the integrated product. The bending of the flexible PCBs creates stress/strain at the flexible PCBs' I/O connections. Any additional bending/warping by the DIMM PCB could add to these stresses/strains—perhaps to the point of failure. The presence of the base PCBs 3321, 332_2 on the DIMM PCB side of the flexible PCBs adds another mechanical interface that can absorb stresses/strains induced by DIMM PCB bending/warping which, in turn, protects the flexible PCB's soldered connections.

FIG. 3d shows yet another approach in which the DIMM PCB has multiple, different flexible PCBs 313_1, 313_3 connected to a same DIMM PCB side (both DIMM PCB sides have multiple, different flexible PCBs but the flexible PCBs of only one DIMM side are labeled for illustrative ease). Notably, the sides of the DIMM PCB are staggered or stepped to allow “head room” for the connection of multiple flexible PCBs to a same DIMM PCB side in a lower region of the DIMM PCB (the region of the DIMM PCB that is close to the motherboard).

FIG. 3e shows the approach of FIG. 3d but with more than one base PCB at the motherboard interface. Specifically, a first base PCB 3311 supports connections from a first side of the DIMM PCB whereas a second base PCB 3312 supports connections from a second, opposite side of the DIMM PCB. Multiple base PCBs 331_1, 331_2 can also help reduce stresses/strains at the motherboard interface—particularly as I/O counts between the DIMM PCB and the motherboard increase.

Specifically, if the approach of FIG. 3d is taken (one base PCB at the motherboard interface) and a large base PCB is needed to accommodate many hundreds or thousands of I/O connections between the DIMM PCB and the motherboard, the single large base PCB can introduce mechanical challenges. For example, if the motherboard warps or bends, a large base PCB at the motherboard board interface is more likely to “pop-out” of the motherboard connector. Here, multiple, smaller base PCBs 331_1, 331_2 as observed in FIG. 3d can more easily adapt to motherboard warpage resulting in (potentially) a more reliable connection between the DIMM and the motherboard.

FIG. 3f shows the approach of FIG. 3e but where there exists a base PCB at the DIMM side of the flexible PCBs. As discussed above with respect to FIG. 3c, base PCBs at the DIMM side of a flexible PCB can help protect the flexible PCB's solder joints, and, moreover, as discussed just above with respect to FIG. 3e, multiple base PCBs at the motherboard interface can help improve the reliability of the DIMM's connection to the motherboard. Thus, the approach of FIG. 3f represents an approach having connection reliability enhancements at both ends of the flexible PCBs.

FIGS. 3g, 3h and 3i correspond to FIGS. 3d, 3e and 3f but where one side of the DIMM PCB is staggered and the other side of the DIMM PCB is planar. Notably, the approaches of FIGS. 3a, 3b and 3c are suitable for lower I/O counts between the DIMM PCB and motherboard whereas the staggered approaches of FIGS. 3g, 3h and 3i can be used to accommodate extremely high I/O counts between the DIMM PCB and motherboard. By contrast, the approaches of FIGS. 3g, 3h and 3i can be used as an intermediate solution in which moderate I/O counts exist between the DIMM PCB and motherboard.

FIGS. 3j and 3k pertain to another approach in which a flexible PCB 313_5 extends beneath the DIMM PCB when the integrated product is fully inserted into the motherboard connector. Here, as observed in FIG. 3j, flexible PCB 313_5 bends in such a manner that it extends beneath the DIMM PCB. Running flexible PCBs beneath the DIMM PCB can help reduce the overall footprint size of the integrated product because it lessens the extent to which the I/Os at the motherboard interface spread-out away from the DIMM PCB.

FIG. 3k shows that the DIMM PCB and/or the motherboard connector can be shaped to include “studs” or “posts” 333 between which there is space 334 beneath the DIMM PCB that flexible PCBs can extend into and/or run through. I/O pads 335 can also be incorporated at the motherboard interface directly beneath the space as well to compact the overall size of the footprint as just described above.

FIG. 3l further shows that rails 336 can also be integrated into the mechanical connection between the integrated product and the motherboard to further stabilize the integrated. For example, ideally, rotation of the DIMM PCB about the z axis is diminished and/or eliminated, which, should further alleviate stress at various (if not all) flexible PCB I/O junctions and/or base PCB I/O junctions.

Such posts can be integrated into the motherboard apart from the motherboard connector (e.g., by running through holes in the motherboard and connector that are secured (e.g., with nuts, bolts, etc.) at the backside of the motherboard). Alternatively or in combination, the posts can be mechanically integrated with the motherboard connector (e.g., a molded plastic motherboard connector can be molded to include such posts that rise up from the floor of the connector that faces the integrated product).

FIG. 3m depicts yet another embodiment in which the flexible PCB 313_1, 313_2 is directly attached (e.g., by pad soldering) to the DIMM PCB and the motherboard. The direct soldering of the flexible PCB to the DIMM PCB and the motherboard eliminates vias that run through a PCB that is inserted between the flexible PCB and DIMM PCB and motherboard (e.g., as depicted in FIG. 3c). The elimination of the vias helps improve transmission line characteristic impedance integrity (vias typically correspond to a change in characteristic impedance along the signal propagation path).

Here, motherboard side “blocks” 341_1, 341_2 are solid pieces that are mechanically attached to the motherboard (e.g., with studs, pins, etc.) that run through holes in the flexible PCB at the motherboard end. Likewise DIMM PCB side “blocks” 342_1, 342_2 are solid pieces that are mechanically attached to the DIMM PCB (e.g., with studs, pins, etc.) that run through holes in the flexible PCB at the DIMM PCB end. The blocks 341, 343 provide mechanical stability to the flexible PCB soldering junction that exists at their corresponding flexible PCB end. In various embodiments the blocks 341, 342 are PCBs that, e.g., contain signal wires for lower speed signals and/or power/ground bus wiring.

FIG. 3n shows another embodiment that is akin to the embodiment of FIG. 3m but there is just the flexible PCB with both ends of the flexible PCB integrated on both the motherboard side and the DIMM PCB side.

It is important to point out that FIGS. 3a through 3m depict only a subset of the various implementation possibilities. For instance, although embodiments above have emphasized socketed pad connections between the integrated product and a connector that is affixed to the motherboard, in other embodiments the integrated product can be directly soldered to the motherboard (e.g., with solder balls at the product/motherboard interface). Moreover, base PCBs at the motherboard side and/or the DIMM PCB side of a flexible PCB may or may not be present in such implementations (e.g., I/Os on the motherboard side of a flexible PCB are soldered directly to the motherboard).

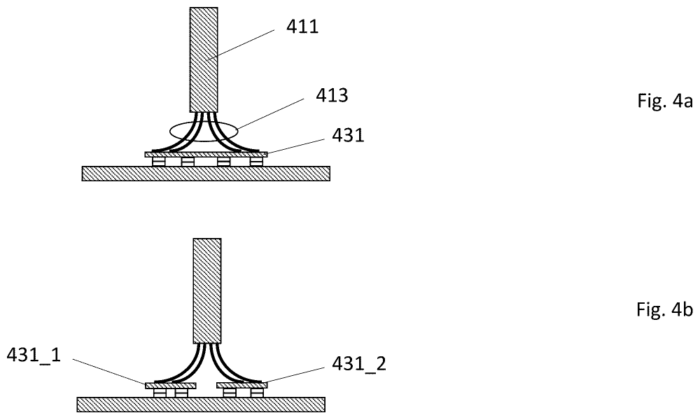

FIGS. 4a and 4b pertain to yet another embodiment in which flexible PCB transmission line strips 413 emanate from the bottom edge of the DIMM PCB 411. That is, for example, the flexible PCBs 413 are extensions of the DIMM PCB 411 where both the DIMM PCB 411 and the flexible PCB strips 413 were monolithically formed during a single PCB manufacturing process. FIG. 4a shows a first embodiment in which the embedded/integrated flexible PCBs 413 are coupled to a single base PCB 431. FIG. 4b shows another embodiment that includes multiple base PCBs 4311, 431_2.

How many base PCBs are utilized, or if any base PCBs are utilized, can vary from embodiment to embodiment consistent with the teachings described above. Notably, however, with the flexible PCBs extending from the bottom edge of the DIMM PCB, a mechanical design that creates space beneath the bottom edge of the DIMM PCB, e.g., as discussed above with respect to FIG. 3k, should be utilized.

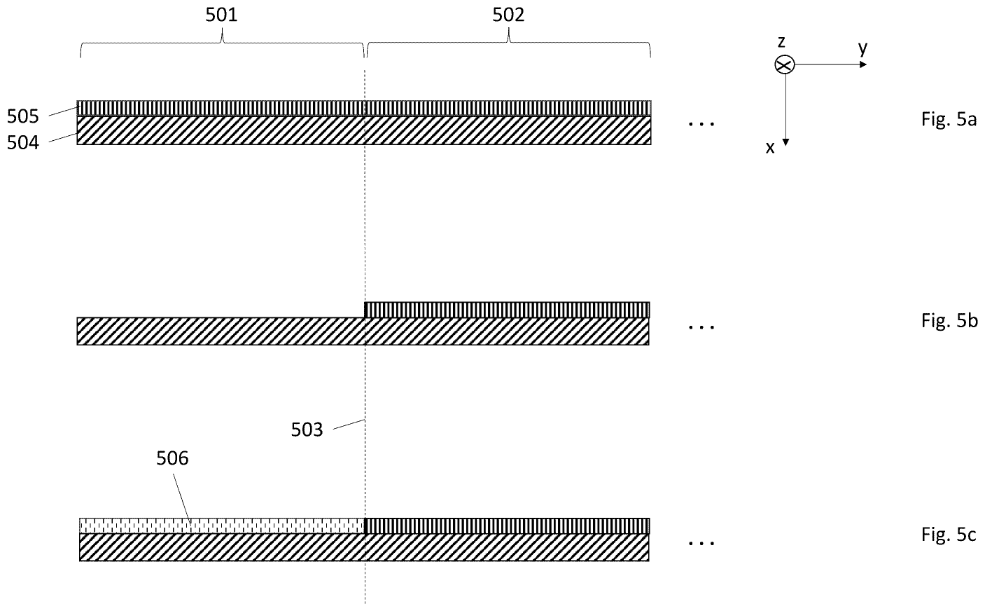

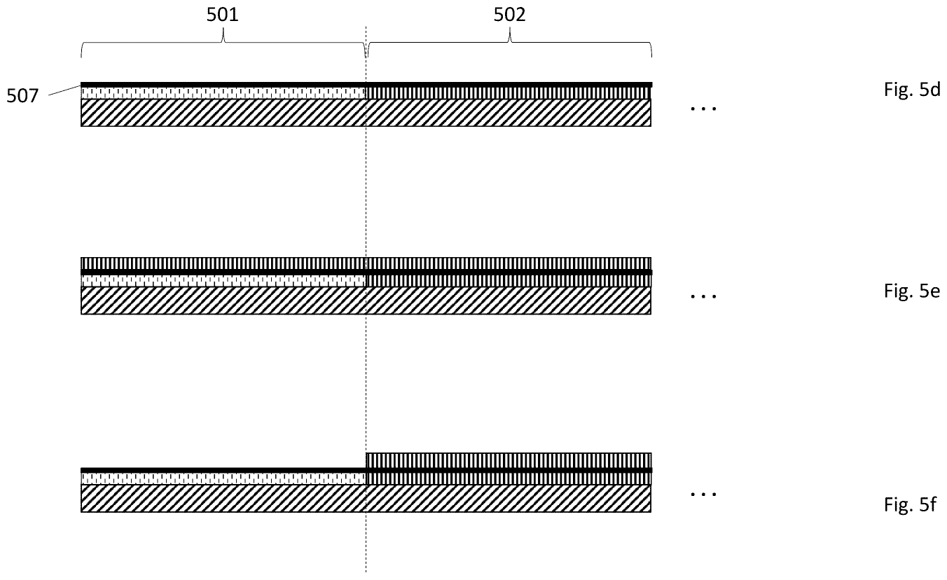

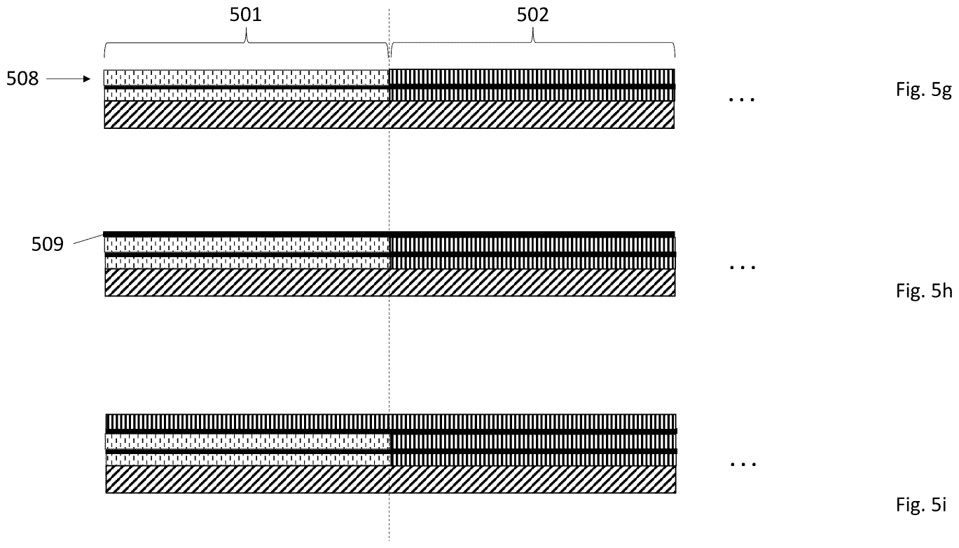

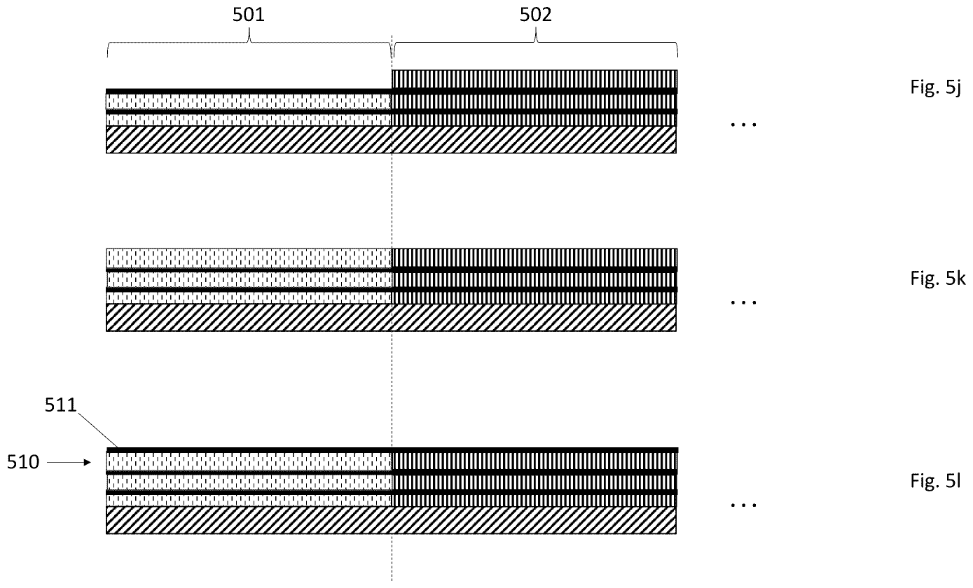

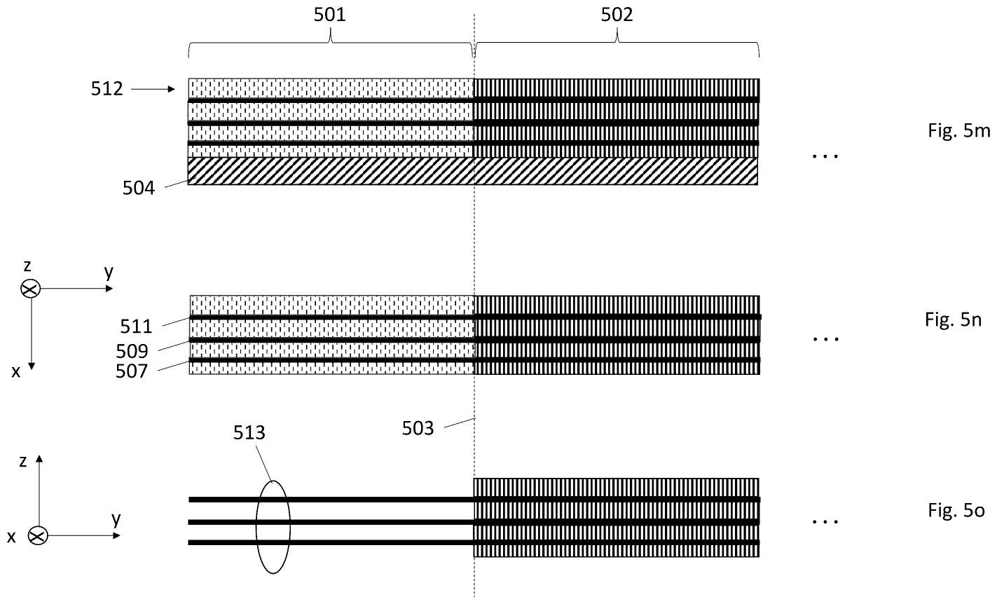

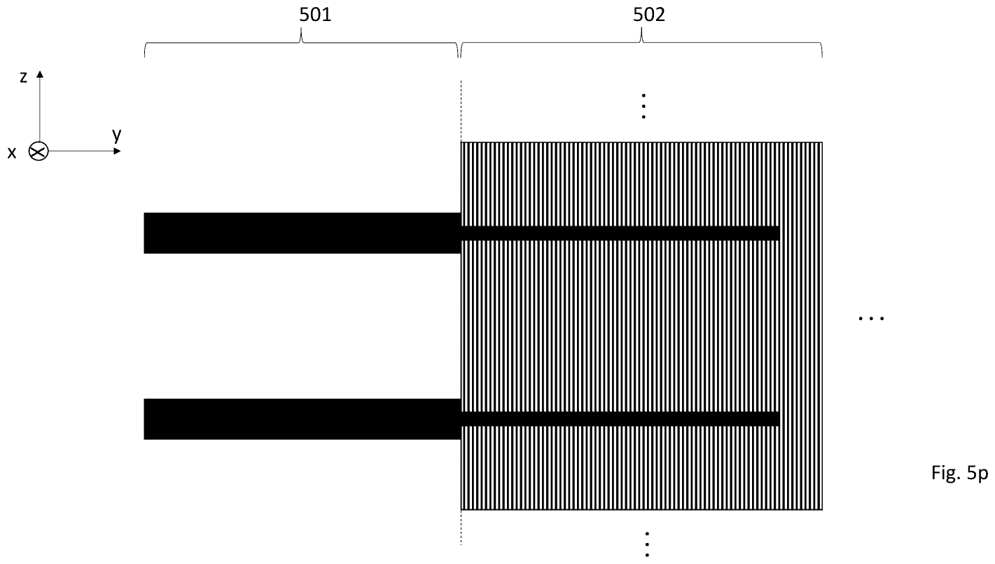

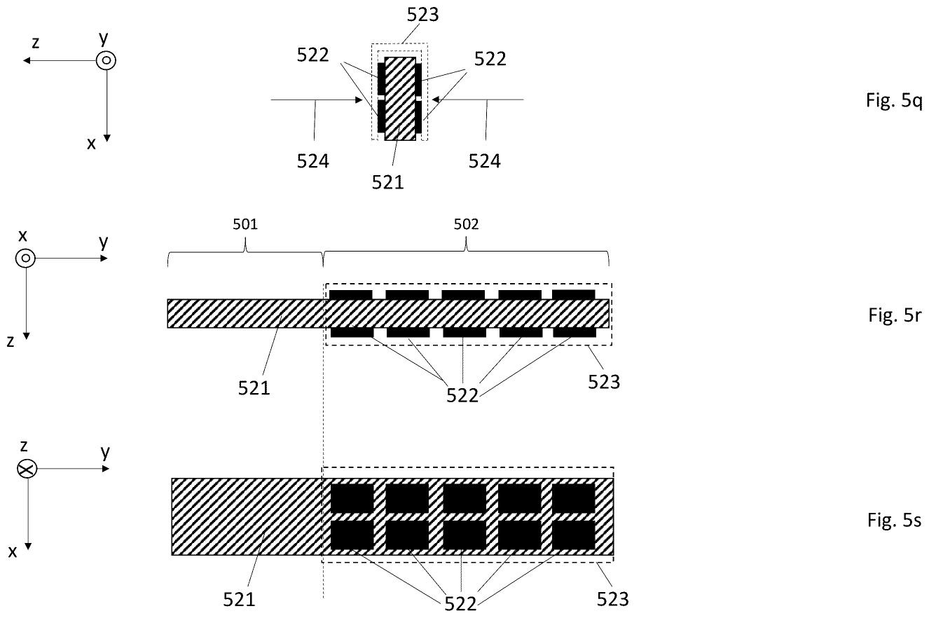

FIGS. 5a through 5p pertain to an embodiment for monolithically forming an integrated DIMM PCB with embedded/integrated flexible PCB extensions as described just above. FIG. 5a shows a substrate 504 after a first dielectric layer 505 has been disposed (e.g., deposited) thereon. According to the monolithic PCB manufacturing process, as will become more clear below, region 501 corresponds to the region where the flexible PCBs will be formed and region 502 corresponds to the region where the DIMM PCB will be formed. That is, line 503 corresponds to the bottom edge of the DIMM PCB as depicted in FIGS. 4a and 4b.

FIG. 5b shows the structure of FIG. 5a after the first dielectric layer 505 is patterned (e.g., by way of a photolithographic process) and etched so that first dielectric material 505 is removed in the region 501 where the flexible PCBs will be formed. That is, for example, a layer of photoresist (not depicted in FIG. 5b) is patterned so that the photoresist remains over the first dielectric material 505 in region 502 but is removed in region 501.

Then, as observed in FIG. 5c, a second dielectric layer 506 is disposed on the substrate in region 501. Here, for example, the aforementioned photoresist can be removed before the second dielectric layer 506 is deposited. Then, a thick layer of the second dielectric material 506 is deposited over both regions 501, 502. Then, the structure is planarized to remove excess second dielectric material in both regions 501, 502 which results in the structure observed in FIG. 5c.

As described in more detail below, the first dielectric layer material 505 can have greater stiffness or hardness than the second dielectric layer material 506 (the second dielectric material 506 is softer than the first dielectric material 505). So doing helps to create a DIMM PCB with adequate stiffness to support the DIMM and its semiconductor chips (achieved with the first dielectric) and flexible PCBs with adequate softness so as to easily bend (achieved with the second dielectric).

As observed in FIG. 5d, a first layer of electrically conductive material 507 (e.g., a metal) is formed on both the first and second dielectrics 505, 506. Then, as observed in FIGS. 5e, 5f and 5g, the process of FIGS. 5a, 5b and 5c are repeated to form another dielectric layer 508 having the first dielectric material in region 501 and the second dielectric material in region 502.

Then, as observed in FIG. 5h, a second layer of electrically conductive material 509 is formed on the second layer 508 of first and second dielectrics (e.g., the process of FIG. 5d is repeated). Then, as observed in FIGS. 5i, 5j, 5k and 5l, the process of FIGS. 5e, 5f, 5g and 5h are repeated which forms a third layer 510 of first/second dielectric materials in regions 501/502 and a third layer 511 of conductive material formed thereon. Then, as observed in FIG. 5m, the process of FIGS. 5e, 5f and 5g are again repeated which forms a fourth layer 512 of first/second dielectric materials in regions 501/502.

The substrate 504 is then removed as observed in FIG. 5n (in other embodiments the substrate 504 is not removed and is composed of a flexible dielectric). Notably, the structure in FIG. 5n depicts a coplanar stripline transmission line, akin to the transmission line of FIG. 1a, in which conductive layer 509 corresponds to the inner conductor and conductive layers 507 and 511 correspond to the outer “ground” conductors. As observed in FIG. 5n, the coplanar stripline of FIG. 5n includes first (harder) dielectric material 505 in the DIMM PCB region 502 and a second (softer) dielectric material 506 in the flexible PCB region 501 to effect the desired stiffness of the two different regions.

Changing dielectric materials along a transmission line can change the characteristic impedance of the transmission line (the transmission line has different characteristic impedances in regions 501 and 502), which, in turn, can induce reflections when a signal passes from one of regions 501, 502 to the other of regions 501, 502. Reflections are a form of signal corruption (signal integrity is compromised). However, as described in more detail below with respect to FIG. 5p, the dimensions of the micro strip formed with the inner conductor 509 can be different within regions 501 and 502 to lessen the impedance mismatch at the junction 503 of regions 501/502.

Continuing with a discussion of the monolithic PCB manufacturing process, notably, FIGS. 5a through 5n depicted the PCB according to a cross section view in which only one flexible PCB is visible. FIG. 5o, by contrast, shows the PCB in an orthogonal orientation so that multiple flexible PCBs 513 that are formed in region 501 can be observed.

Here, to construct the multiple PCBs, the inner conductive layer 509 is patterned to form multiple striplines that run through the PCB, and, all four layers of the second dielectric material 506 is etched along the x axis between the conductive striplines to form separate flexible PCB strips 513 (the second dielectric material remains above and below the conductive layers in the flexible PCB region 501 so that the structure observed in FIG. 5n is preserved).

Notably, the particular embodiment of FIG. 5o shows one stripline transmission line per flexible PCB (three striplines and three separate flexible PCBs are observed). However, in other embodiments, multiple striplines can be packed into a same flexible PCB by not etching the second dielectric material between neighboring stripline within a same flexible PCB.

FIG. 5p shows a more detailed embodiment of the view of FIG. 5o. Here, as described in more detail above, changing the dielectric material along a planar transmission line can cause a characteristic impedance mismatch at the junction 503 between the two different dielectrics, which, in turn, can potentially compromise signal integrity.

A solution is to have different coplanar stripline structural dimensions in the two different regions 501, 502 so that that the coplanar stripline has same or approximately the same characteristic impedance through both regions 501, 502. As just one example, if the second dielectric 506 not only has lower stiffness than the first dielectric but also lower permittivity (Dk) than the first dielectric, the characteristic impedance will be lower in region 501 than region 501 if the width of the stripline is kept constant through both regions 501, 502.

However, as observed in FIG. 5p, the width of the micro-strip can be widened in region 501 to compensate/offset the effect that the change in dielectric material has on the characteristic impedance of the transmission line in regions 501 to region 502. With this approach, there is little difference in the characteristic impedance of the transmission line in the two regions 501, 502 resulting in little/no reflections at the interface between the two regions.

In other embodiments, the first and second dielectrics of the different regions 501, 502 and the widths of the respective strip-lines in these regions to effect a single transmission line are all considered to strike a sufficient balance between DIMM PCB stiffness in region 502, the flexibility of the flexible PCB 501 in region 501 and signal integrity through both regions. As such, some appreciable impedance mismatch is allowed at interface 503 to allow for a harder DIMM PCB and a softer flexible PCB, but, signal integrity is not overly comprised despite the impedance mismatch (e.g., the impedance mismatch results in only a 10% or 15% reflection of signal energy at interface 503).

Note that the base PCB/flexible PCB/base PCB monolithic structure discussed above with respect to FIGS. 4a and 4b can be created by having another PCB region like region 502 to the left of the flexible PCB region 501 in the process of FIGS. 5a through 5p. Here, region 502 corresponds to one of the base PCBs and the aforementioned other region like region 502 to the left of region 501 corresponds to the other of the PCBs. Region 501 corresponds to the flexible PCB between the two base PCB regions.

FIGS. 5q, 5r and 5s pertain to another approach in which the same dielectric and metal layers are used for both regions 501 and 502 (the flexible PCB and DIMM PCB are structurally the same). Having same metal and same dielectric layers 521 in both regions 501, 502, in theory, should eliminate reflections altogether at the 501/502 interface. However, according to this approach, the DIMM PCB portion 502 can be flexible like the flexible PCB portion 501. A flexible DIMM PCB 502, by itself, may not properly serve as a substrate for the DIMM's semiconductor chips 522.

As such, in order to assist the DIMM PCB's role as a substrate for the DIMM's semiconductor chips 522 the DIMM PCB portion 502 and its semiconductor chips 522 can be encased in a cover clip 523 that exerts inward force 524 toward the DIMM PCB in a manner that compresses the chips 522 into the DIMM PCB 502 so that the cover clip 523 and DIMM PCB 502 with chips 522 have sufficient rigidity to stand upright in the motherboard socket and handle the forces associated with DIMM removal/insertion from/to the socket.

In various embodiments, as suggested above, the flexible PCB (whether monolithically integrated with the DIMM PCB or a separate attachment to the DIMM PCB) is composed of a flexible dielectric having low loss (low Dk, e.g., 5.0 or lower). Examples include polytetrafluroethylene (PTFE) or other per- and polyfluoroalkyl substances (PFAS). Dupont TK having Dk=2.5@10 GHz and Df=0.002@10 GHz and Panasonic LCP having Dk=3@10 GHz and Df=0.0016@10 GHz are suitable materials.

In various embodiments, the DIMM product and motherboard connector are designed to conform to an industry standard such as a memory technology standard promulgated by the Joint Electron Device Engineering Council (JEDEC). Possible double data rate (DDR) JEDEC standards that could be written to include teachings described herein include DDR6 or subsequent JEDEC DDR standards. Such a JEDEC implementation, or other implementation, could be integrated into a computing system.

In various embodiments the teachings above are applied to a stacked memory chip module solution, such as a JEDEC High Bandwidth Memory (HBM) solution. Here, the DIMM PCB is aligned approximately parallel with the motherboard so that there is a bottom side that faces the motherboard and a top side upon which memory chips are stacked. Here, one or more flexible PCBs can extend from the bottom and/or top side of the DIMM PCB according to any of the connection techniques described in FIGS. 3a through 3n and FIGS. 4a and 4b.

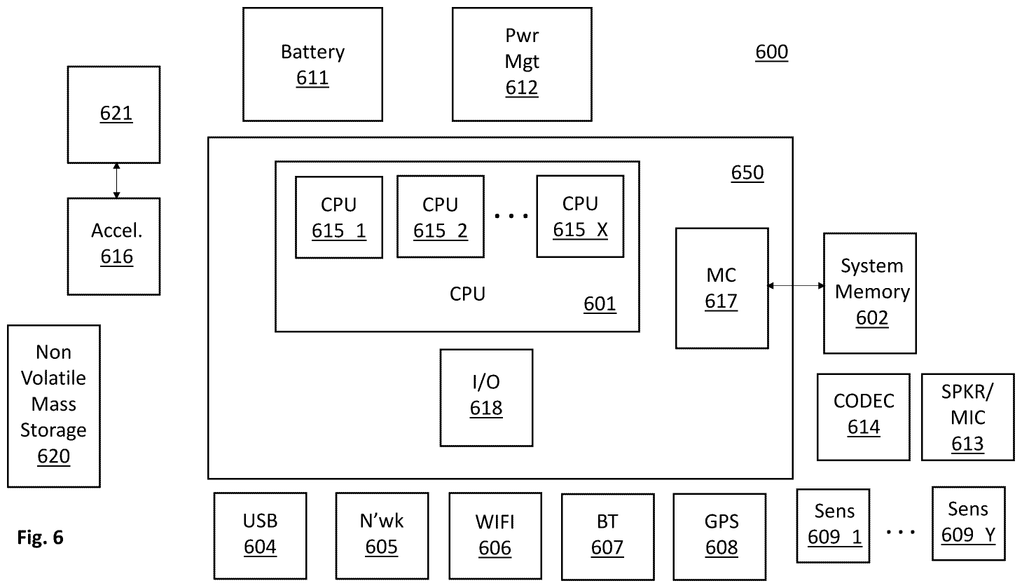

Components of a basic computing system are presented in FIG. 6. As observed in FIG. 6, the basic computing system 600 may include a central processing unit (CPU) 601 (which may include, e.g., a plurality of general purpose processing cores 615_1 through 615_X). The CPU 601 can be integrated on a multi-core processor 650 that also includes an integrated main memory controller 617 and I/O control hub 618.

A system memory 602 (also referred to as “main memory”) is coupled to the memory controller 602. One or more accelerator chips, such as one or more GPUs 616, can also be coupled to its own dedicated local memory 621. The teachings provided above with respect to a DIMM solution having an flexible PCB connection between the motherboard and DIMM PCB I/Os can be used to implement either or both of the system memory 617 and accelerator local memory 621. Such implementations can be JEDEC DDR implementations.

The computing system 600 of FIG. 6 also includes various I/O functions coupled to the I/O control hub 618. Examples include a local wired point-to-point link (e.g., universal serial bus (USB)) interface 604, various network I/O and/or interface functions 605 (such as an Ethernet interface and/or cellular modem subsystem), a wireless local area network (e.g., WiFi) interface 606, a wireless point-to-point link (e.g., Bluetooth) interface 607 and a Global Positioning System interface 608, various sensors 609_1 through 609_Y, one or more cameras 610, a battery 611, a power management control unit 612, a speaker and microphone 613 and an audio coder/decoder 614.

The computing system also includes non-volatile mass storage 620 which may be the mass storage component of the system and which can be composed of one or more non-volatile mass storage devices (e.g., solid state drives (SSDs), hard disk drive (HDDs), etc.).

The computing system 600 can also include an integrated display (e.g., touchscreen, flat-panel), e.g., in the case of personal computing solutions (e.g., personal computer (PC), laptop, smartphone, etc.).

In the case of larger systems, the computing system can be realized as a traditional server computer. In the case of disaggregated computing systems, various high performance computing components, such as the CPU 601, the accelerators 616, mass storage 620, and/or the main memory 602 can be implemented with respective components (e.g., processors 650, accelerator chips, memory DIMMs, SSDs, etc.) within their own respective (e.g., rack mountable) chassis that is separated from one or more other chassis have high performance components one another by a network.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

The teachings above describe an apparatus. The apparatus includes a memory module. The memory module includes a first printed circuit board having a first transmission line. The first printed circuit board has memory chips disposed thereon. The memory module includes a second printed circuit board having a second transmission line that is coupled to the first transmission line to form a signal path through the first and second printed circuit boards. The second printed circuit board has greater flexibility than the first printed circuit board. The memory module includes a connector to align an I/O that is coupled to the second transmission line with a corresponding I/O that is associated with a motherboard that is to send and/or receive a signal to and/or from the signal path.

In a first further embodiment the I/O is a component of the second printed circuit board.

In a second further embodiment the I/O is a component of a third printed circuit board that the second printed circuit board is coupled to.

In a third further embodiment, the first transmission line is coupled to the second transmission line through a third printed circuit board.

In a fourth further embodiment, the first printed circuit board has a third transmission line and the apparatus further includes a third printed circuit board having a fourth transmission line that is coupled to the third transmission line to form a second signal path through the first and third printed circuit board. The third printed circuit board has greater flexibility than the first printed circuit board.

In a fifth further embodiment, the first printed circuit board has a stepped face and the second printed circuit board is coupled to a first step of the stepped face and a third circuit board is coupled to a second step of the stepped face.

In a sixth further embodiment, the first and second printed circuit boards are monolithically integrated. A seventh further embodiment combines the fifth and sixth further embodiments.

In an eighth further embodiment, at least a portion of the second printed circuit board is positioned to reside underneath the first printed circuit board when the memory module is connected to the motherboard. A ninth further embodiment combines the sixth and eighth embodiments. A tenth further embodiment combines the seventh and eighth embodiments.

The teachings above also describe the above described memory module plugged into a motherboard.

The teachings above also describe a computing system. The computing system includes a plurality of processing cores; a memory controller; a main memory coupled to the memory controller; an accelerator; and, a local memory coupled to the accelerator, where, at least one of the main memory and the local memory includes the above described memory module.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a memory module comprising a), b) and c) below:
a) a first printed circuit board comprising a first transmission line, the first printed circuit board comprising memory chips disposed thereon;
b) a second printed circuit board comprising a second transmission line that is coupled to the first transmission line to form a signal path through the first and second printed circuit boards, the second printed circuit board having greater flexibility than the first printed circuit board; and,
c) a connector to align an I/O that is coupled to the second transmission line with a corresponding I/O that is associated with a motherboard that is to send and/or receive a signal to and/or from the signal path.

2. The apparatus of claim 1 wherein the I/O is a component of the second printed circuit board.

3. The apparatus of claim 1 wherein the I/O is a component of a third printed circuit board that the second printed circuit board is coupled to.

4. The apparatus of claim 1 wherein the first transmission line is coupled to the second transmission line through a third printed circuit board.

5. The apparatus of claim 1 wherein the first printed circuit board comprises a third transmission line and the apparatus further comprises:
a third printed circuit board comprising a fourth transmission line that is coupled to the third transmission line to form a second signal path through the first and third printed circuit boards, the third printed circuit board having greater flexibility than the first printed circuit board.

6. The apparatus of claim 1 wherein the first printed circuit board has a stepped face and the second printed circuit board is coupled to a first step of the stepped face and a third circuit board is coupled to a second step of the stepped face.

7. The apparatus of claim 1 wherein the first and second printed circuit boards are monolithically integrated.

8. The apparatus of claim 1 wherein at least a portion of the second printed circuit board is positioned to reside underneath the first printed circuit board when the memory module is connected to the motherboard.

9. An apparatus, comprising:
a memory module that is plugged into a motherboard, the memory module comprising a), b) and c) below:
a) a first printed circuit board comprising a first transmission line, the first printed circuit board comprising memory chips disposed thereon;
b) a second printed circuit board comprising a second transmission line that is coupled to the first transmission line to form a signal path through the first and second printed circuit boards, the second printed circuit board having greater flexibility than the first printed circuit board; and,
c) a connector to align an I/O that is coupled to the second transmission line with a corresponding I/O that is associated with the motherboard.

10. The apparatus of claim 9 wherein the I/O is a component of the second printed circuit board.

11. The apparatus of claim 9 wherein the I/O is a component of a third printed circuit board that the second printed circuit board is coupled to.

12. The apparatus of claim 9 wherein the first transmission line is coupled to the second transmission line through a third printed circuit board.

13. The apparatus of claim 9 wherein the first printed circuit board comprises a third transmission line and the apparatus further comprises:
a third printed circuit board comprising a fourth transmission line that is coupled to the third transmission line to form a second signal path through the first and third printed circuit boards, the third printed circuit board having greater flexibility than the first printed circuit board.

14. The apparatus of claim 9 wherein the first printed circuit has a stepped face and the second printed circuit board is coupled to a first step of the stepped face and a third circuit board is coupled to a second step of the stepped face.

15. The apparatus of claim 9 wherein the first and second printed circuit boards are monolithically integrated.

16. The apparatus of claim 9 wherein at least a portion of the second printed circuit board is positioned to reside underneath the first printed circuit board when the memory module is connected to the motherboard.

17. A computing system, comprising:
a plurality of processing cores;
a memory controller;
a main memory coupled to the memory controller;
an accelerator;
a local memory coupled to the accelerator, wherein, at least one of the main memory and the local memory comprise a memory module comprising a), b) and c) below:
a) a first printed circuit board comprising a first transmission line, the first printed circuit board comprising memory chips disposed thereon;
b) a second printed circuit board comprising a second transmission line that is coupled to the first transmission line to form a signal path through the first and second printed circuit boards, the second printed circuit board having greater flexibility than the first printed circuit board; and,
c) a connector to align an I/O that is coupled to the second transmission line with a corresponding I/O that is associated with a motherboard that is to send and/or receive a signal to and/or from the signal path.

18. The computing system of claim 17 wherein the I/O is a component of the second printed circuit board.

19. The computing system of claim 17 wherein the first printed circuit board comprises a third transmission line and the apparatus further comprises:
a third printed circuit board comprising a fourth transmission line that is coupled to the third transmission line to form a second signal path through the first and third printed circuit boards, the third printed circuit board having greater flexibility than the first printed circuit board.

20. The computing system of claim 17 wherein the first and second printed circuit boards are monolithically integrated.
